(19) United States
(12) Patent Application Publication
(10) Pub. No.: US 2010/0006987 A1
(43) Pub. Date: Jan. 14, 2010

(54) INTEGRATED CIRCUIT PACKAGE WITH EMI SHIELD

(76) Inventors: Rajen Murugan, Garland, TX (US); Kenneth R. Rhyner, Rockwall, TX (US); Peter R. Harper, Lucas, TX (US); Souvik Mukherjee, Dallas, TX (US)

Correspondence Address: TEXAS INSTRUMENTS INCORPORATED, P O BOX 655474, M/S 3999, DALLAS, TX, 75265, US

(21) Appl. No.: 12/169,908

(22) Filed: Jul. 9, 2008

(51) Int. Cl. H01L 23/552; G06F 17/50

(52) U.S. Cl. 257/659; 716/10; 257/E23.114

(57) ABSTRACT

An integrated circuit (IC) device (200) includes an electronic substrate (201) having a plurality of layers (120) including at least one first electrically conductive layer and a lower surface dielectric layer. The IC device also includes an electrically conductive surface layer (126) disposed on the dielectric layer and coupled to a ground terminal (210) for the electronic substrate (201) for blocking electromagnetic interference (EMI). In the IC device, the conductive surface layer (126) includes an EMI shield region (204) over at least a portion of the dielectric layer. The EMI shield region (204) includes at least one solid area (206) and one or more adhesion areas (207) having a plurality of openings (208) arranged aperiodically in the adhesion areas (207).

### FIELD OF THE INVENTION

The present invention is directed to integrated circuit packages, and more particularly to integrated circuit packages having electromagnetic interference (EMI) shielding.

### BACKGROUND

As the demand for faster, smaller electronic products with increased functionality is increased, stacked packaging schemes, such as package-on-package (POP) packaging, have become increasingly popular. The stacking of different semiconductor packages using stacked packages typically reduces the required footprint size for a semiconductor package in an electronic product. Furthermore, stacked packages can provide a modular solution for constructing electronic devices by permitting different combinations of stacked semiconductor packages using only a few semiconductor package footprints.

Some types of integrated circuits (ICs), including those used in stacked packages, are known to radiate significant electromagnetic energy during periods of operation. The electromagnetic energy radiated by such devices can interfere with the operation of other devices or circuits in the vicinity of the radiating IC, including other ICs in the stacked package. A number of techniques have been used to reduce the level of electromagnetic interference (EMI) coupling between ICs in a stacked package. In particular, existing techniques have used solid metal shielding layers or periodically patterned metal mesh patterned layers between one or more ICs and other components in a stacked package. These shielding layers are typically formed on a surface of one of the packages in the stacked package prior to stacking the packages or attaching ICs using underfill or molding compounds. These shielding layers are then coupled to a ground terminal to form a ground plane which is used to block EMI between ICs and other package components above and below the shield layer.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

As previously described, incorporating EMI generating ICs into stacked IC packages, including POP packages, can result in significant EMI between different ICs in the stacked packages. The Present Inventors have observed that EMI-induced signal problems occur when digital radio frequency ICs and memory comprising ICs are both included in a single stacked package or on a single package substrate on the system-on-chip (SoC). Although certain techniques for blocking EMI are available and have been implemented in stacked packages, the usefulness of such techniques is generally limited. For example, in the case of solid metal shield layers, conventional underfill and molding compound materials typically do not adhere well to such layers, reducing reliability of such packages. In the case of periodically patterned metal mesh layers, adhesion is improved due to more of the underlying package surface being exposed, however, the periodic mesh opening size typically required to promote good adhesion is typically too large to block certain wavelengths of EMI between ICs in stacked packages. Although the mesh opening size can be reduced to improve EMI shielding, the result is a decrease in adhesion, as in the case of solid metal shield layers. In response to these problems, embodiments of the present invention provide improved shielding layers for stacked packages. In particular, the Present Inventors have discovered that conventional EMI shielding layers can be replaced with an EMI shielding layers comprising solid portions in selected areas and having an aperiodic arrangement of openings in other areas of the EMI shielding layer. When the solid areas are formed over EMI-generating or EMI-sensitive electrical traces in the IC device, the solid areas block EMI for these electrical traces, while the aperiodic arrangement of openings in other areas promotes enhanced adhesion of underfill and molding compounds.

In a first embodiment of the present invention, an integrated circuit (IC) device is provided. The IC device includes an electronic substrate comprising at least one electrically conductive layer and a lower surface dielectric layer. The IC device further includes an electrically conductive surface layer disposed on the lower dielectric layer and coupled to a ground terminal for blocking electromagnetic interference (EMI). The conductive surface layer is a patterned layer including an EMI shield region having at least one solid area and one or more adhesion areas with openings. In the surface layer, a portion of the openings are arranged aperiodically.

In a second embodiment of the present invention, a method for designing an integrated circuit device is provided. The method includes providing a design for an electronic substrate having at least one electrically conductive layer and a lower surface dielectric layer. The method also includes generating a pattern for an electrically conductive surface layer disposed on the dielectric layer and coupled to a ground terminal for blocking electromagnetic interference (EMI). The pattern for the conductive surface layer defines an EMI shield region over at least a portion of the dielectric layer. The pattern includes at least one solid area and one or more adhesion areas having a plurality of openings, where at least a portion of the openings in the pattern are arranged aperiodically.

### BRIEF DESCRIPTION OF THE DRAWINGS

FIG. 1 shows an exemplary integrated circuit device arranged according to an embodiment of the present invention.

FIG. 2 shows a schematic of a portion of an EMI shield region according to an embodiment of the present invention.

FIG. 3 shows an exemplary layout of a portion of an integrated circuit device according to an embodiment of the present invention.

FIG. 4 shows an exemplary layout of a portion of an integrated circuit device according to an embodiment of the present invention.

FIG. 5 shows an exemplary layout of a portion of an integrated circuit device according to an embodiment of the present invention.

FIG. 6 shows an exemplary graph comparing electromagnetic coupling as a function of frequency for a pair of shielded electrical traces in integrated circuit devices with a conventional EMI shield and EMI shields according to an embodiment of the present invention.

FIG. 7 shows an exemplary graph comparing input impedance as a function of time for a shielded electrical trace in integrated circuit devices with a conventional EMI shield and EMI shields according to an embodiment of the present invention.

FIG. 8 shows an exemplary method for designing an integrated circuit device including EMI shields in accordance with an embodiment of the present invention.

### DETAILED DESCRIPTION OF THE DRAWINGS

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

Embodiments of the present invention comprise integrated circuit devices and design methods that provide improved electromagnetic interference (EMI) shielding. The inventive EMI shields generally provide both improved electrical and mechanical properties for integrated circuit devices in a stacked arrangement as compared to conventional methods. In particular, the Present Inventors have discovered that by replacing conventional EMI shields in stacked integrated circuit devices with an EMI shield including an aperiodic arrangement of openings, EMI can be effectively blocked while still promoting reliable adhesion.

An “integrated circuit device”, as used herein, can refer to any type of package, with or without a functional die attached thereto, including stacked IC packages. An “electrical trace” as used herein, refers to any electrical conductor in the either a package substrate or within a functional die. In the various embodiments of the present invention, the electrical traces to be shielded can be either EMI-sensitive or EMI-generating traces. EMI-sensitive traces can include one or more electrical traces carrying signals that can be altered when exposed to an electromagnetic radiation at one or more wavelengths. For example, asymmetrical noise coupling from the “EMI-generating” trace to the inputs of the LNA (low noise amplifier) will impact its noise floor sensitivity. EMI-generating traces can include one or more electrical traces generating electromagnetic radiation at one or more wavelengths during operation of the IC device. For example, single-ended high-speed memory clock lines, switching with fast rise time and at high frequency, can couple noise to signal nets that are connected to external devices over flex cables. Collectively, these EMI-generating and EMI-sensitive traces can be referred to as “EMI-reactive” traces. In the various embodiments of the present invention, the inventive EMI shields can be used as a shield for any type of EMI-reactive trace.

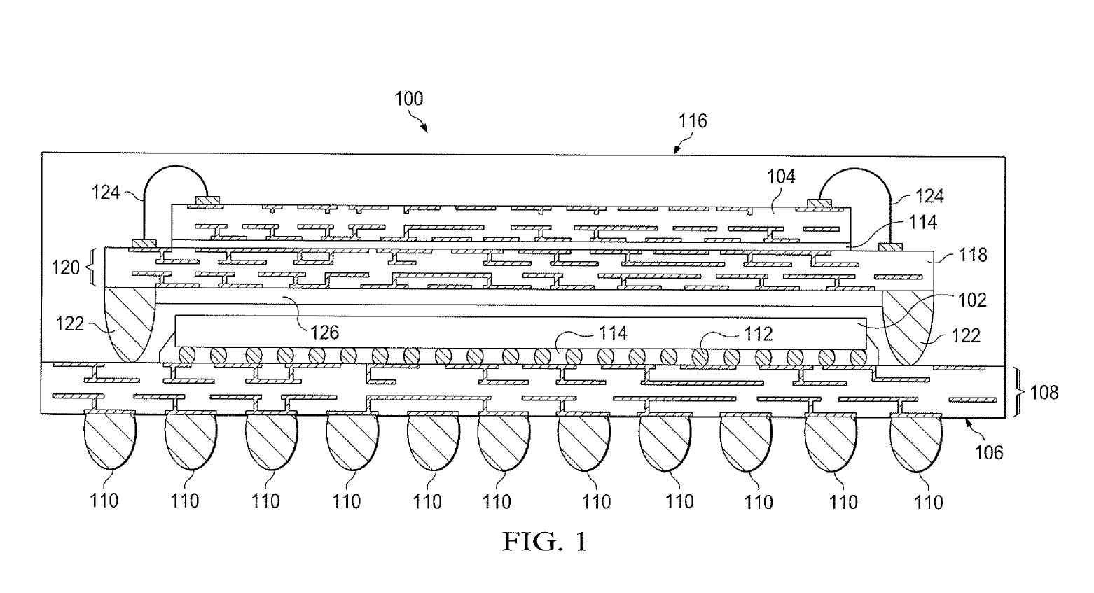

FIG. 1 shows an exemplary integrated circuit device arranged according to an embodiment of the present invention. As shown in FIG. 1, an integrated circuit device 100 can include a first 102 and a second 104 functional die in a stacked or vertical arrangement. The first die 102 can be mounted onto a first electronic substrate 106. The term “electronic substrate”, as used herein refers to any type of printed circuit board used for the stacked package. In the various embodiments of the present intervention, electronic substrates can be constructed using a variety of techniques. By way of example, and not by way of limitation, electronic substrates can be constructed using laminate substrate technologies, including rigid and/or flexible laminate technologies, and ceramic substrate technologies, including thin film, thick film, and co-fired (HTCC, LTCC) ceramic technologies.

The first electronic substrate 106 can include a plurality of dielectric and electrically conducting layers 108 to couple at the first die 102 to first circuit coupling features 110 of the first electronic substrate 106. The first die 102 can be electrically coupled to the first substrate 106 using one or more electrical bonding features 112 on the first die 102, the first substrate 106, or both. In the exemplary circuit in FIG. 1, a flip-chip arrangement is illustrated. However, the invention is not limited in this regard and the first die 102 can also be electrically coupled to the first substrate 106 using any other type of electrical bonding methods, including wire bonding or tab bonding methods. The first die 102 can be mechanically coupled to the first substrate 106 generally using any type of adhesive material. For example, as shown in FIG. 1, underfill 114 and/or molding compound 116 materials can be used to mechanically couple the first die 102 to the first substrate 106.

The second die 104 can be similarly configured and similarly mounted onto a second electronic substrate 118. The second electronic substrate 118 can also include a plurality of dielectric and electrically conducting layers 120 to couple at the second die 104 to second coupling features 122 of the second electronic substrate 118. The second die 104 can be electrically coupled to the second substrate 118 using one or more electrical bonding features 124 on the second die 104, the second substrate 118, or both. In the exemplary circuit in FIG. 1, a wire bond arrangement is illustrated for the second die 104. As previously described, the invention is not limited in this regard and the second die 104 can also be electrically bonded to the second substrate 118 using other bonding methods, such as flip chip or tab bonding. The second die 102 can also be mechanically coupled to the second substrate 118, as described above for the first die 102 and the first substrate 106.

To provide EMI shielding between the first die 102 and the second die 104, an EMI shield 126 can be formed on a surface of the second electronic substrate 118. The second die 104 and second substrate 118 can then be electrically coupled to the first die 102 and second substrate 106. Subsequently or in combination, the various components can then be mechanically coupled using underfill 114 or molding compound 116 in between. Although FIG. 1 illustratively shows the shield layer 126 attached to the lower surface of the second electronic substrate 118, the invention is not limited in this regard. The arrangement in FIG. 1 can be appropriate when the EMI generating die is the first die 106 and EMI needs to be prevented from reaching EMI-sensitive portions in the second die 104, the second substrate 118, or both. However, in some embodiments, the second die 104 can be the EMI generating die. In such embodiments, the EMI shield 126 can be located as shown on FIG. 1 if no EMI sensitive traces are present in the second substrate 118. However, if EMI sensitive traces are located therein, the EMI shield layer can be attached to an upper surface of the second substrate 118. Furthermore, even though only two functional dies are shown in FIG. 1, one of ordinary skill in the art will recognize that the present invention can be implemented in IC devices having any number of stacked functional dies, as well as any number of electronic substrates. Additionally, even though EMI shield layer 126 is shown to be a single region that extends over the width of the first 102 and second 104 dies, the invention is not limited in this regard. One of ordinary skill in the art will recognize that the EMI shield region in the EMI shield layer 126 can have any size and need only extend over a portion of the area between the dies. Furthermore, multiple shield regions can be used to protect different portions of the dies 102 or 104.

The Present Inventors note that the basic requirement for forming an EMI shield is that the walls of the enclosure should be of a sufficient thickness. That is, the thickness should be sufficient large such that the EMI affects only a outer portion of the thickness (skin depth) of the EMI shield layer. The thickness required can vary as the electrical conductivity of the enclosure material varies and as the type of EMI varies. Generally, as electrical conductivity of the enclosure material increases, the thickness of material required to block EMI decreases and vice versa. Therefore, an electromagnetic layer requires a layer that is not only electrically conductive, but that has a thickness greater than a skin depth for the EMI to be blocked. In cases where the EMI generating IC is within the enclosure, the same principles generally apply with the exception that skin depth is measured from the interior of the enclosure. For example, in a typical stacked package, the metal layer thickness typically required for providing adequate shielding from adjacent RF-generating IC's can be at least 10 um of an alloy primarily comprising copper, such as between 15 and 20 um.

Regardless of location and size of the EMI shield layer 126, proper adhesion between the first die 102 (or the second die 104), the second substrate 118, and the EMI shield layer 126 therebetween, can be provided by patterning of a EMI shield region in the EMI shield layer 126 according to the various embodiments of the present invention. That is, an EMI shield region having solid areas overlapping EMI reactive traces and having an aperiodic arrangement of openings elsewhere. A “solid area” of the EMI shield region, as used herein, refers to an area of the EMI shield region having no openings in the EMI shield layer 126.

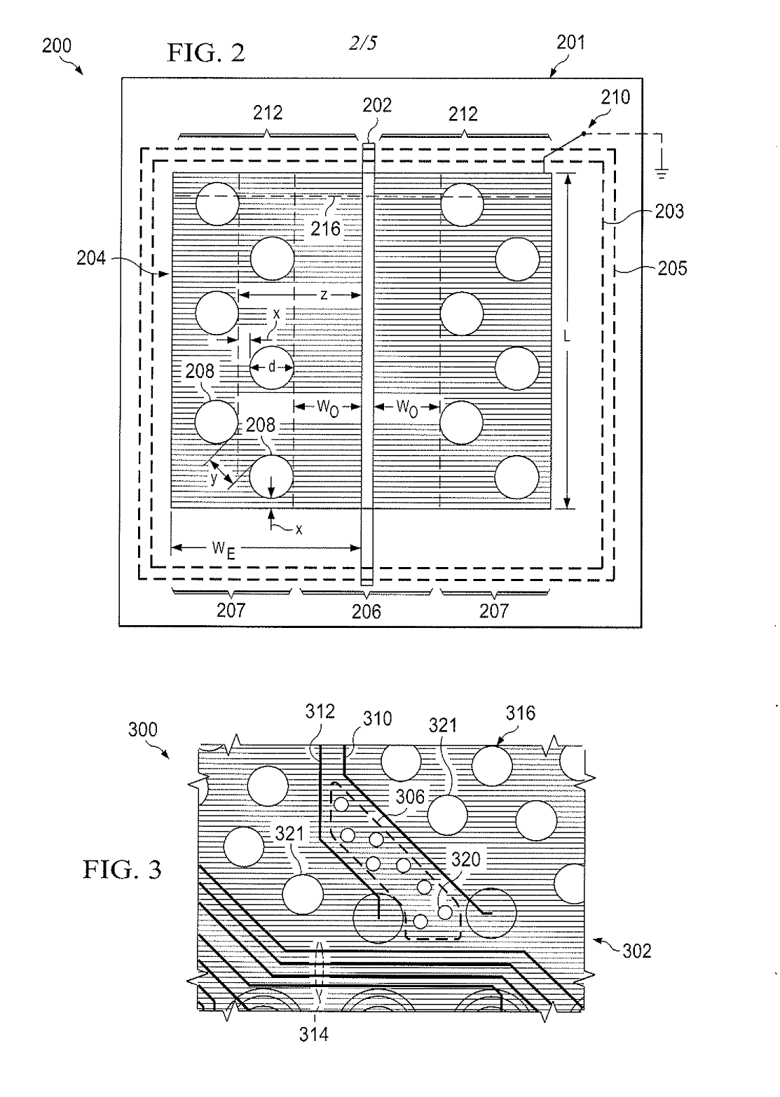

FIG. 2 shows a schematic of a portion of an EMI shield region according to an embodiment of the present invention. As shown in FIG. 2, an integrated circuit device 200 can include one or more electrical traces 202 that need to be shielded. That is, the electrical traces 202 on a first functional die 203 (footprint shown), an electronic substrate 201, or a second functional die 205 (footprint shown). Although a first die 203 is shown to be smaller than both the second die 205 and the electronic substrate 201, the invention is not limited in this regard. In the various embodiments of the present invention, the sizes of the various components can vary according to the design required for the integrated circuit device 200.

In the various embodiments of the present invention, at least one EMI shield region 204 can be formed for the IC device 200 on the electronic substrate 201. The shield region 204 can be coupled to a grounding terminal 210 of the IC device 200. To provide sufficient EMI shielding, the EMI shield region 204 can include at least one solid area 206 and one or more adhesive areas 207 having one or more openings 208. In some embodiments, the EMI shield region 204 can have a width equal to that of the shielded trace 202 (i.e., W_{O}=0). In other embodiments, the EMI shield region 204 can overlap the edges of the traces 202 by at least a minimum amount W_{O}. Such an overlap ensures that EMI does not reach the traces 202 via diffraction effects at the edges of the EMI shield region 204 or due to EMI traversing the IC device at angles other than perpendicular to the EMI shield region 204. Accordingly, one of ordinary skill in the art will recognize that the minimum trace overlap W_{O} can vary as the distance between the traces 202 to be protected and the EMI shield region 204 varies.

As previously described, one aspect of the present invention is to provide openings 208 in the EMI shield region 204 for promoting adhesion of the EMI shield region 204 to the electronic substrate 201 underneath the EMI shield region 204. Accordingly, as shown in FIG. 2, the adhesion regions 207 can include one or more openings 208 that provide a sufficient surface area to promote good adhesion. In the various embodiments of the present invention, the width of the openings 208 can vary between 10 um and 300 um, such as 50 um, 100 um, 150 um, and 200 um. Furthermore, to further ensure a sufficient area to promote reliable adhesion of the shield region 204, the number and size of the openings 208 can be selected depending on process conditions, IC design, and package design. Typically, as the area of the openings is increased, less shielding is provided, albeit with better adhesion. As the area of the openings is decreased, more shielding is provided, but with less adhesion. As one of ordinary skill in the art will recognize, the number and size of openings may be ultimately limited based on the wavelength of the EMI in question and the particular manufacturing process. For example, some electronic substrate materials can require a larger surface area for reliable adhesion. Therefore, the area of the openings can comprise between 20% and 80% of the total area of the shield region 204. In some embodiments, this range can be limited based on process conditions to between 25% and 75% or between 30% and 70%.

Although FIG. 2 only shows round openings 208, the invention is not limited in this regard. In the various embodiments of the present invention, openings of any geometry, including that of polygons, ellipses, or other shapes, can be used to form openings.

In the various embodiments of the present invention, the number and position of the openings can vary depending on the total area and geometry of portions 212 of the shield region 204 extending beyond the edges of the traces 202. Although the extending portion 212 is shown in FIG. 2 to extend from an edge of the electrical trace 202 to the edge of the EMI shield region 204, the invention is not limited in this regard. In some embodiments, extending portions 212 (and thus the adhesion areas 207) can be bounded by one or more electrical traces, by one or more edges of the EMI shield region 204, or any combination thereof.

As the number of openings 208 in an EMI shield region 204 is increased, an increased area of the electronic substrate 201 is exposed and the likelihood of good adhesion of the underfill and molding layers generally increases. However, as the size of the openings is further increased or their spacing is decreased, the openings 208 can become more poorly formed in the EMI shield region 204. In some cases, this can cause some of the openings 208 to encroach on the solid portions 206. This encroachment can reduce the effectiveness of the EMI shield region 204 in blocking EMI. Therefore, in the various embodiments of the present invention, the position and number of openings can be dependent on one or more design rules. The design rules can be used to then determine the maximum number of openings can be placed without significantly affecting the integrity of the solid areas 206 of the EMI shield region. That is, the design rules ensure that after the integrated circuit device 200 is formed, the solid areas 206 remain of a sufficient width to block EMI, as previously described.

A first design rule can be that the distance (x) between the edge of an opening 208 and an edge of the EMI shield region 204 should be greater than or equal to a minimum edge to edge spacing. A second design rule can be that the distance between adjacent openings 208 should also be greater than or equal to a minimum edge to edge spacing (y). One of ordinary skill in the will recognize that this spacing can be the same or different in the various embodiments of the present invention. The third design rule can be that the minimum lateral distance between any traces being shielded and an edge of an opening 208 should be at least the minimum width (W_{O}) for the shield region. Accordingly, one of ordinary skill in the art will recognize that for a round opening 208 having a diameter d, the extending portion 212 needs to have at least an area equal to W_{E}·L, where L≧d+2x and W_{E}≧x+d+W_{O}. However, the invention is not limited in this regard. In some embodiments, an opening 208 can overlap with an edge of the shield region 204 (i.e., x≦0) as shown by edge 216 in FIG. 2.

In various embodiment of the present invention, an aperiodic arrangement of openings results because the arrangement of the openings is based on the geometry of each of the individual adhesion areas as opposed to the overall geometry of the EMI shield region. Accordingly, variations in the area and geometry of each adhesion area results in variations in the number and placement of openings. However, the various embodiments of the present invention are not limited to solely an aperiodic distribution of openings of a single size, as shown in FIG. 2, but can include an aperiodic distribution of openings of different sizes, as shown in FIG. 3. The different sizes allow smaller openings to be inserted in adhesion regions that would not typically not allow placement larger sized openings.

FIG. 3 shows an exemplary layout of a portion of an integrated circuit device according to an embodiment of the present invention. In particular, FIG. 3 shows an integrated circuit device layout 300 with an EMI shield region 302 to be formed on an electronic substrate. The EMI shield region includes at least a first adhesion area 306. In FIG. 3, the first adhesion 306 bounded by EMI reactive electrical traces 310, 312, and 314. In adhesion area 306, the spacing between these adjacent traces 310, 312, and 314 is insufficient to allow placement of a large size opening, such as opening 316. However, the spacing is sufficient to allow placement of one or more openings of a smaller size 320. Accordingly, in these smaller adhesion areas, smaller sized openings 320 can be used instead. In some embodiments, in addition to utilizing smaller sized openings 320, the design rule spacing utilized can also be decreased, as the processing margin for forming such smaller openings 320 is typically larger.

As previously described, the openings in the EMI shield region can vary in size. Accordingly, one of ordinary skill in the ail will recognize that the electrical traces 310, 312, and 314 need not have openings of the same size on both sides. Rather the selection of opening size in a particular portion of the EMI shield region 302 is determined based on its area and geometry. For example, as shown in FIG. 3, other openings 321 surrounding the traces 310 and 312 include openings of a larger size 320.

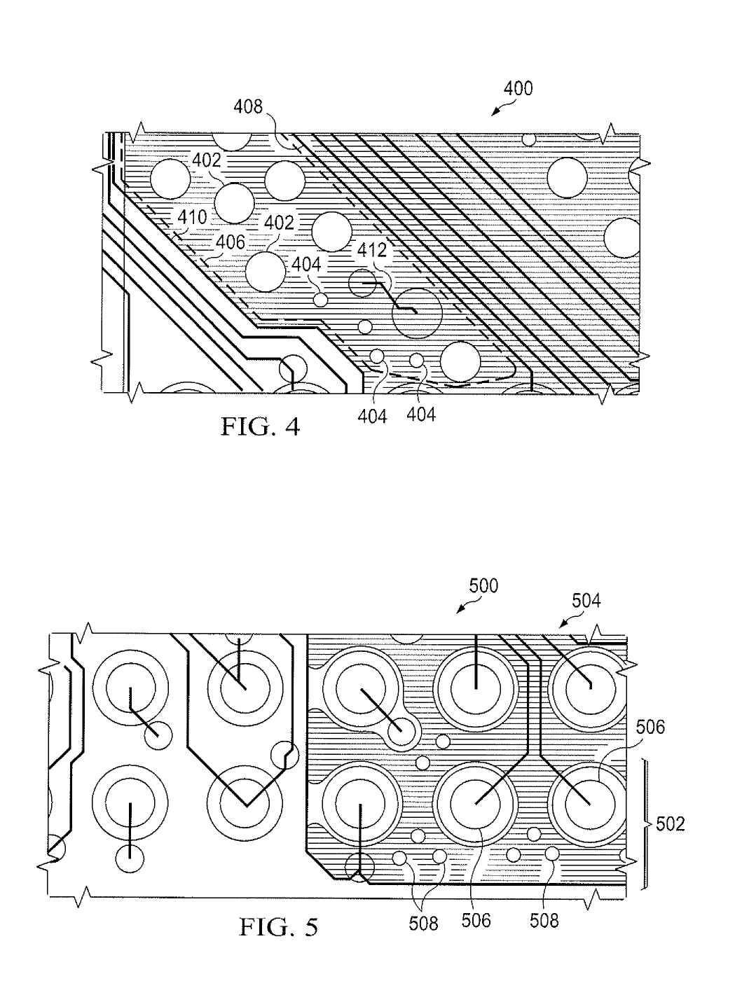

In addition to using openings of different sizes in different adhesion areas, in some embodiments, a mix of differently sized openings can be used in a single adhesion area. FIG. 4 shows an exemplary layout of a portion of an integrated circuit device according to an embodiment of the present invention. In particular, FIG. 4 shows an integrated circuit device layout 400 where openings of a larger size 402 and a smaller size 404 are both used in adhesion area 406. In adhesion area 406, the portion bounded only by traces 408 and 410 allow placement of openings of a larger size 402. However, in areas of portion 408 also bounded by traces 410 and 412, the remaining spacing is insufficient for such larger openings 402. In such areas, openings of a smaller size 404 are used instead. In some cases, no openings can be inserted. For example, in the portion of adhesion area 406 bounded by traces 412 and 408, insufficient spacing is provided for insertion of an opening of any available size. In such cases, the portion would remain solid.

In some embodiments of the present invention, additional openings can also be included in the EMI shield region to improve adhesion along an edge of the EMI shield region or along portions of the EMI shield region in proximity with an edge of the functional die being mechanically attached. This can result in improved resistance against de-lamination along such edges. FIG. 5 shows an exemplary layout of a portion of an integrated circuit device according to an embodiment of the present invention. In particular, FIG. 5 shows an integrated circuit device layout 500 where a portion 502 of an EMI shield 504 that is to be in proximity with an edge of a functional die to be attached is shown. In this portion 502, large size openings 506 can be provided for electrical coupling of the electronic substrate to a die. Typically, the size of such openings is sufficiently large to expose a sufficiently large surface area of the electronic substrate and ensure proper adhesion. However, because stress is typically enhanced in such regions, in the various embodiments of the present invention, additional openings of a smaller size 508 can be placed along the edges of the EMI shield region 504 to increase the area and thus the amount of the adhesion.

As previously described, EMI shield layouts in accordance with the present invention can generally be used to effectively block EMI while promoting adhesion between function die(s) and electronic substrates. In particular, embodiments of the present invention reducing the amount of electromagnetic coupling between EMI reactive traces, resulting in improved performance of a stacked integrated circuit device or coupling within the SoC.

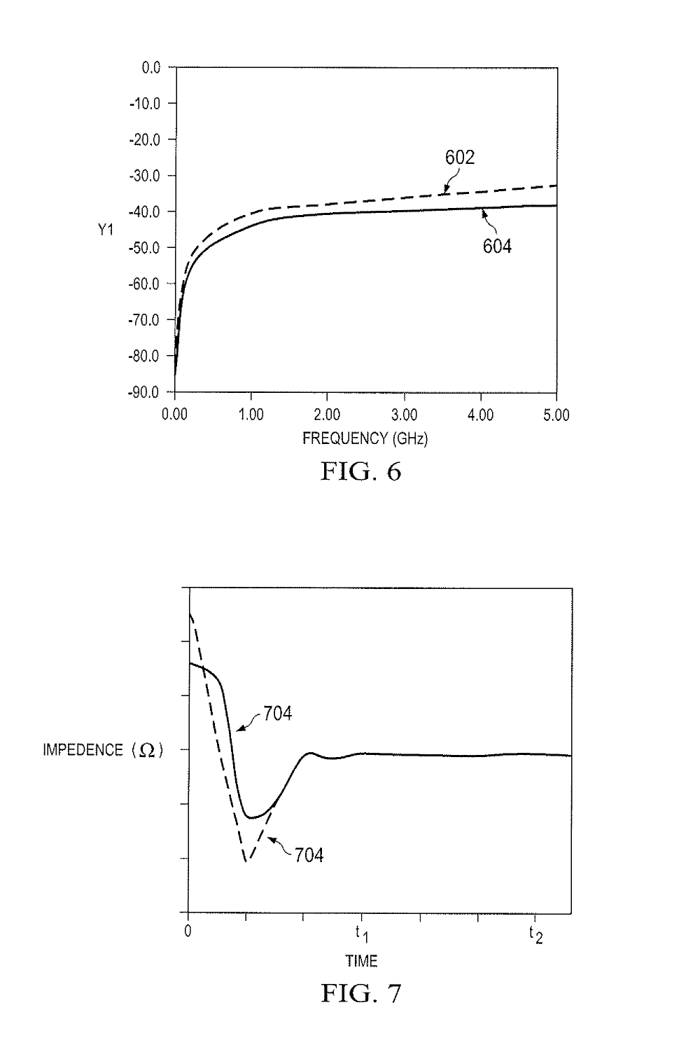

FIG. 6 shows an exemplary graph comparing electromagnetic coupling as a function of frequency for a pair of shielded electrical traces in integrated circuit devices with a conventional EMI shield and EMI shields according to an embodiment of the present invention. In particular, FIG. 6 graphically shows the amount of coupling resulting in an integrated circuit device including a digital radio integrated circuit and a digital memory and processor integrated circuit configured in a stacked arrangement. FIG. 6 shows the admittance ratio (Y1) for a pair of EMI sensitive traces in the stacked integrated circuit device as a function of frequency. For EMI-sensitive circuits, the result of EMI interference is typically an increase in coupling between circuit elements, resulting in a decrease of the admittance ratio due to the increase of EMI-induced impedance. As shown in FIG. 6, over the frequency range of 0 to 5 GHz, the admittance ratio values 602 for an integrated circuit device having a conventional periodic cross-hatched EMI shield region are shown to be approximately 4-6 dB lower as compared admittance ratio values 604 for an integrated circuit device having an EMI shield region according to the various embodiments of the present invention.

As described above, EMI directly impacts the impedance of EMI sensitive traces. In particular, the characteristic impedance or surge impedance can also be affected by EMI, and can result in poor impedance control during operation of an IC in an IC device. FIG. 7 shows an exemplary graph comparing input impedance as a function of time for a shielded electrical trace in integrated circuit devices with a conventional EMI shield and EMI shields according to an embodiment of the present invention. In particular, FIG. 7 shows the characteristic impedance of an EMI sensitive electrical trace in an integrated circuit device including a digital radio integrated circuit and a digital memory and processor integrated circuit configured in a stacked arrangement. FIG. 7 shows impedance of the electrical trace as function of time. As shown in FIG. 7, over time period between 0 and t1 (≦1 ns) the impedance of the electrical trace varies regardless of the EMI shield region design being used. Over the time period between t1 and t2 and beyond (≧1 ns), the impedance reaches a steady state value that is approximately equal regardless of the EMI shield region deign being used. However, as shown in FIG. 7, the magnitude of variation in impedance values 702 for an integrated circuit device having a conventional periodic cross-hatched EMI shield region is shown to be greater as compared the magnitude of variation in impedance values 704 for an integrated circuit device having an EMI shield region according to the various embodiments of the present invention. Accordingly, including an EMI shield region according to the various embodiments of the present invention improves impedance control. Such control can be critical especially when the frequency at which signals are being applied to the EMI sensitive traces is high, since the resulting characteristic impedance will generally be a function of the amount of such switching.

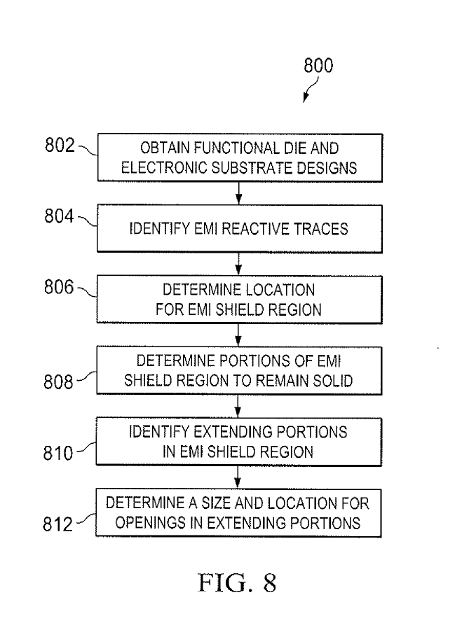

In the various embodiments of the present invention, a design for an EMI shield region can be generated in various ways. FIG. 8 shows an exemplary method 800 for designing an integrated circuit device including EMI shields in accordance with an embodiment of the present invention. Method 800 can be implemented manually by a circuit designer or can be implemented automatically in a design tool including automatic layout and error checking capabilities.

First, in step 802 the designs for the functional dies included in the IC device and the electronic substrate(s) that will be placed in between can be obtained. Once the designs are obtained in step 802, one or more EMI reactive traces in these components can be identified in step 804. That is, the EMI generating traces, the EMI sensitive traces, or both can be identified in the designs. This identification can be based on the types of circuits in the integrated circuit device (known EMI reactive circuit design elements) or empirical data available for the IC device. After the EMI reactive traces are identified, the location for the EMI shield region can be determined in step 806. That is, the proper location on the electronic substrate for the EMI shield region can be selected based on the location of the EMI reactive traces. Such a selection can include not only which surface of the electronic substrate to use for the EMI shield region, but also which portion of the selected surface.

Once the portion of the electronic substrate surface is selected in step 806, the EMI shield region can be defined. Initially, in step 808, the solid areas for the EMI shield region can be determined based on the EMI reactive regions identified in step 804. In some embodiments, the solid areas can be selected based on a design of EMI-reactive traces. The placement of solid areas can be also adjusted as needed to accommodate the presence of other circuits on the surface of the electronic substrate. For example, the design can be adjusted to prevent shorting of circuit elements to the EMI shield region.

Once the solid areas are determined in step 808, the adhesion areas can be identified in step 810. Afterwards in step 812, the location and size of openings for the identified adhesion areas can be determined. In step 812, the location and size of the openings can be determined in several ways. For example, in some embodiments a first adhesion area and a first size of opening can be selected. Based on the design rules, a maximum number of openings of the first size can be placed in selected adhesion area. In other embodiments, a second size can then be selected and a maximum number of openings of the second size can be placed in the remaining portions of the selected adhesion area. This can be repeated for other sizes of openings. The method can then be repeated for other adhesion areas. In still other embodiments, as previously described, once other openings are placed, the regions in proximity to the edge of the EMI shield region or the edge of the functional circuit die to be attached to the electronic substrate can be selected and additional openings can be inserted to enhance adhesion.

These are but a few examples. Accordingly, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and/or the claims, such terms are intended to be inclusive in a manner similar to the term “comprising.”

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

What is claimed is:

1. A integrated circuit device, comprising:
an electronic substrate comprising a first plurality of layers, said first plurality of layers comprising at least one first electrically conductive layer and a lower surface dielectric layer; and
an electrically conductive surface layer disposed on said dielectric layer and coupled to a ground terminal for said electronic substrate, said conductive surface layer for blocking electromagnetic interference (EMI),
wherein said conductive surface layer comprises a patterned layer comprising an EMI shield region over at least a portion of said dielectric layer, wherein said EMI shield region comprises at least one solid area and one or more adhesion areas, wherein said adhesion areas have a plurality of openings, and wherein at least a portion of said openings are arranged aperiodically in said adhesion areas.

2. The device of claim 1, further comprising;
at least one functional die attached to said lower surface dielectric layer or to an upper surface of said electronic substrate, said functional die comprising a second plurality of layers, said second plurality of layers comprising at least one second electrically conductive layer,
wherein one or more portions of at least one among said first and said second electrically conductive layer are EMI reactive, and said wherein said solid areas overlapping at least one of said EMI reactive portions.

3. The device of claim 2, wherein a number, a size, and an arrangement of said openings in each of said adhesion areas is based on an area and geometry of each of said selected areas,

4. The device of claim 3, wherein said solid areas extend beyond said overlapped electrical traces at least a minimum overlap distance.

5. The device of claim 4, wherein a distance between an edge of one of said openings and a nearest edge of said EMI shield region or an edge of a nearest one of said openings is greater than or equal to a minimum edge to edge spacing, and wherein a distance between said edge of said one opening and a nearest one of said electrical traces is greater than or equal to a minimum opening to trace spacing.

6. The device of claim 5, wherein said openings in said one portion comprise at least a first opening having a first area and at least a second opening having a second area, said first area greater than said second area.

7. The device of claim 6, wherein said minimum edge to edge spacing and said minimum opening to trace spacing are greater for said first opening than for said second opening.

8. The device of claim 1, wherein a total area of said openings is between 20% and 80% of the total area defined by a perimeter of said EMI shield region.

9. A method for designing an integrated circuit device, the method comprising:
providing a design for an electronic substrate comprising a first plurality of layers, said first plurality of layers comprising at least one first electrically conductive layer and a lower surface dielectric layer; and
generating a pattern for an electrically conductive surface layer disposed on said dielectric layer and coupled to a ground terminal for said electronic substrate and for blocking electromagnetic interference (EMI),
wherein said pattern for said conductive surface layer defines an EMI shield region over at least a portion of said dielectric layer, wherein said pattern includes at least one solid area and one or more adhesion areas, wherein said adhesion areas have a plurality of openings, and wherein at least a portion of said openings in said pattern are arranged aperiodically in said adhesion areas.

10. The method of claim 9, wherein said providing further comprises:
providing a design of for at least one functional die to be attached to said lower surface dielectric layer or to an upper surface of said electronic substrate, said functional die comprising a second plurality of layers, said second plurality of layers comprising at least one second electrically conductive layer,
wherein one or more portions of at least one among said first and said second electrically conductive layer are EMI reactive, and wherein said solid areas in said generated pattern overlap at least one of said EMI reactive portions.

11. The method of claim 10, wherein said generating further comprises determining a number, a size, and an arrangement of said openings in said adhesion areas based on an area and geometry of said adhesion areas.

12. The method of claim 11, wherein said generating further comprises overlapping said EMI reactive portions by at least a minimum overlap distance.

13. The method of claim 12, wherein said generating further comprises positioning each one of said openings such that a distance between an edge of one of said openings and a nearest edge of said EMI shield region or an edge of a nearest one of said openings is greater than or equal to a minimum edge to edge spacing and such that a distance between said edge of said one opening and a nearest one of said electrical traces is greater than or equal to a minimum opening to trace spacing.

14. The method of claim 13, wherein said openings in said one portion comprise at least a first opening of a first size and at least a second opening of a second size, wherein said first size is larger than said second size.

15. The method of claim 14, wherein said minimum edge to edge spacing and said minimum opening to trace spacing are greater for said first opening than for said second opening.

16. The method of claim 11, wherein said generating further comprises:
selecting one of said adhesion areas;
for said selected one of said adhesion areas, determining one or more a first arrangements of said openings of said first size;
identifying a selected arrangement from said first arrangements having a largest number of said openings of said first size; and
inserting openings of said first size into said pattern according to said selected arrangement.

17. The method of claim 16, further comprising:
determining at least a second arrangement of said openings of said second size for a remaining portion of said selected one of said adhesion areas after inserting said openings of said first size;
identifying a one of said second arrangements having a largest number of said openings of said second size; and
inserting openings of said second size into said pattern according to said identified second arrangement.

18. The method of claim 11, wherein said generating further comprises selecting a number, a size, and an arrangement of said openings to provide a total area for said openings is between 20% and 80% of the total area defined by a perimeter of said EMI shield region.

19. An integrated circuit device, comprising:
an electronic substrate comprising a plurality of substrate layers, said plurality of substrate layers comprising at least one electrically conductive substrate layer;
a first functional die attached to a first surface of said electronic substrate, said one functional die comprising a first plurality of die layers, said first plurality of die layers comprising at least one first electrically conductive die layer;
a second functional die attached to a second surface of said electronic substrate, said one functional die comprising a second plurality of die layers, said second plurality of die layers comprising at least one second electrically conductive die layer;
an electrically conductive surface layer disposed between said electronic substrate and one of said first and said second die, said conductive surface layer for blocking electromagnetic interference (EMI),
wherein said conductive surface layer is patterned to define an EMI shield region over at least a portion of said dielectric layer, wherein said EMI shield region comprises at least one solid area and one or more adhesion areas, wherein said adhesion areas have a plurality of openings of one or more sizes, and wherein at least a portion of said openings are arranged aperiodically,
wherein one or more portions of at least one among said substrate and said die electrically conductive layers are EMI reactive, and said wherein said solid areas overlapping at least one of said EMI reactive portions.
